(19) United States
(12) Patent Application Publication
(10) Pub. No.: US 2002/0043685 A1
(43) Pub. Date: Apr. 18, 2002

(54) Repair structure for thin film transistor-liquid crystal display

(75) Inventors: Jia-Shyong Cheng, Hsinchu Shien (TW); Shou-Jen Chang, Hsinchu (TW); Jack Tsai, Taipei Shien (TW)

Correspondence Address: VOLPE AND KOENIG, P.C., SUITE 400, ONE PENN CENTER, 1617 JOHN F. KENNEDY BOULEVARD, PHILADELPHIA, PA, 19103, US

(73) Assignee: Hannstar Display Corp., Taipei (TW)

(21) Appl. No.: 09/935,187

(22) Filed: Aug. 22, 2001

(30) Foreign Application Priority Data
Oct. 16, 2000 (TW) 089121605

(51) Int. Cl. H01L 27/01; H01L 27/12; H01L 31/0392

(52) U.S. Cl. 257/347

(57) ABSTRACT

A repair structure co-constructed with a storage capacitance in a pixel unit of a thin film transistor-liquid crystal display for repairing defects of said thin film transistor-liquid crystal display is provided. The repair structure includes a first conducting structure as a first electrode of the storage capacitance, an insulating structure formed on the first conducting structure to be a dielectric material of the storage capacitance, a wrapped conducting structure wrapped in the insulating structure, and a second conducting structure as a second electrode of the storage capacitance, wherein when the storage capacitance is welded, the defects are repaired by the wrapped conducting structure.

### FIELD OF THE INVENTION

The present invention relates to a repair structure, and more particularly to a repair structure for repairing defects of a thin film transistor-liquid crystal display.

### BACKGROUND OF THE INVENTION

Recently, the development of liquid crystal display (LCD) is remarkable. The working principle of the liquid crystal display is based on the phenomenon that the alignment condition of liquid crystal molecules is changed by applying an electric field to change the path of light passing through the liquid crystal molecules and the display effect of changing in light and shade is further achieved.

FIG. 1 is a schematic view illustrating a unit circuit block of a thin film transistor liquid crystal display. A thin film transistor 11 is controlled by the voltage Vs of a scan line for switching the statuses of “on” and “off”. The voltage Vd of a data line is applied to a liquid crystal 12 located between a pixel electrode 131 and a common electrode 132 for changing the alignment condition of the liquid crystal 12 and further controlling the light transmittance of the liquid crystal 12. Thus, the emission intensity from a light source 14 at the back of the liquid crystal display will be changed while the light reaches to the eyes of a user for achieving the display effect of the changing in light and shade. A storage capacitance 15 is used for reinforcing the device characteristics.

A thin film transistor-liquid crystal display is formed by fabricating the foresaid components on a display. However, during the fabricating process, bright dots are produced on the pixels controlled by the thin film transistor due to the failure of fabricating the thin film transistor by mistakes. The image quality of the thin film transistor-liquid crystal display is reduced. Presently, a repair circuit is used in a thin film transistor-liquid crystal display for solving the foresaid problem.

Please refer to FIG. 2(a). A storage capacitance 21 formed on a gate electrode in a thin film transistor-liquid crystal display is used a lot in the prior art because the storage capacitance 21 has a high aperture ratio and good image quality. The sectional view taken along the line A-A′ is shown in FIG. 2(b). For increasing the quality of thin film transistor-liquid crystal display, the storage capacitance 21 is a structure of metal/insulating layer/metal. The metal/insulating layer/metal structure is formed on a substrate 22 in sequence of a gate conducting structure 23, a gate insulating layer 24, a protecting layer 25 and a pixel electrode structure 26. The defects are reduced by separately depositing the two insulating layers (the gate insulating layer 24 and the protecting layer 25). Because the thickness of the two insulating layers (the gate insulating layer 24 and the protecting layer 25) is larger than 5,000 angstroms, the storage capacitance having a metal/insulating layer/metal structure is not easily destroyed by a laser. Thus, the welding effect is reduced and the repair quality is controlled with difficulty.

In order to overcome the foresaid drawbacks, the present invention provides a repair structure co-constructed with a storage capacitance in a pixel unit of a thin film transistor-liquid crystal display for repairing defects of the thin film transistor-liquid crystal display.

### SUMMARY OF THE INVENTION

It is an object of the present invention to provide a repair structure co-constructed with a storage capacitance in a pixel unit of a thin film transistor-liquid crystal display for repairing defects of the thin film transistor-liquid crystal display.

In accordance with the present invention, the repair structure includes a first conducting structure as a first electrode of the storage capacitance, an insulating structure formed on the first conducting structure to be a dielectric material of said storage capacitance, a wrapped conducting structure wrapped in the insulating structure, and a second conducting structure as a second electrode of the storage capacitance, wherein when the storage capacitance is welded, the defects are repaired by the wrapped conducting structure.

In addition, the insulating structure includes a first insulating structure formed on the first conducting structure, and a second insulating structure formed under the second conducting structure, wherein the wrapped conducting structure is wrapped by the first insulating structure and the second insulating structure.

The first insulating structure could be a gate insulating layer of the thin film transistor-liquid crystal display and made of a material selected from a group consisting of silicon oxide, silicon nitride and silicon oxynitride. The second insulating structure could be a protecting layer and made of a material selected from a group consisting of silicon oxide, silicon nitride and silicon oxynitride.

Preferably, the first electrode is made of a material selected from a group consisting of chromium, molybdenum, tungsten molybdate, titanium, tantalum, aluminum, copper and the combination thereof. The second electrode is made of a material selected from a group consisting of indium oxide, tin oxide and indium tin oxide. When the insulating structure is destroyed by a laser, an electric connection between the second conducting structure, the wrapped conducting structure and the first conducting structure is made.

It is another object of the present invention to provide a method for fabricating a repair structure co-constructed with a storage capacitance in a pixel unit of a thin film transistor-liquid crystal display for repairing defects of said thin film transistor-liquid crystal display.

In accordance with the present invention, the method includes steps of a) forming a first conducting structure as a first electrode of the storage capacitance, b) forming a first insulating structure on the first conducting structure, c) forming a wrapped conducting structure on the first insulating structure, d) forming a second insulating structure on the first insulating structure and the wrapped conducting structure, wherein the wrapped conducting structure is wrapped by the first insulating structure and the second insulating structure, and e) forming a second conducting structure as a second electrode of the storage capacitance on the second insulating structure, wherein when the storage capacitance is welded, the defects are repaired by the wrapped conducting structure.

Preferably, the first conducting structure is made of a material selected from a group consisting of chromium, molybdenum, tungsten molybdate, titanium, tantalum, aluminum, copper and the combination thereof. The first insulating structure is a gate insulating layer of the thin film transistor-liquid crystal display and made of a material selected from a group consisting of silicon oxide, silicon nitride and silicon oxynitride.

In addition, the wrapped conducting structure is made of a material selected from a group consisting of chromium, molybdenum, tungsten molybdate, titanium, tantalum, aluminum, copper and the combination thereof. The second insulating structure could be a protecting layer and made of a material selected from a group consisting of silicon oxide, silicon nitride and silicon oxynitride. The second conducting structure is made of a material selected from a group consisting of indium oxide, tin oxide and indium tin oxide.

Thus, when the insulating structure is destroyed by a laser, an electric connection between the second conducting structure, the wrapped conducting structure and the first conducting structure is made.

In addition, the wrapped conducting structure is formed simultaneously with a data line structure of the thin film transistor-liquid crystal display.

The present invention may best be understood through the following descriptions with reference to the accompanying drawings, in which:

### BRIEF DESCRIPTION OF THE DRAWINGS

FIG. 1 is a schematic view illustrating a unit circuit block of a thin film transistor liquid crystal display according to the prior art;

FIG. 2(a) is a schematic view showing the layout of the storage capacitance formed on the gate electrode in the thin film transistor-liquid crystal structure according to the prior art;

FIG. 2(b) is a sectional view taken along the line A-A′ region in FIG. 2 (a) showing the storage capacitance formed on the gate electrode in the thin film transistor-liquid crystal structure according to the prior art;

FIG. 3(a) is a schematic view showing the layout of the repair structure comprised in the thin film transistor-liquid crystal display according to the preferred embodiment of the present invention; and

FIG. 3(b) is a sectional view taken along the line B-B′ in FIG. 3(a) showing the repair structure comprised in the thin film transistor-liquid crystal display according to the preferred embodiment of the present invention.

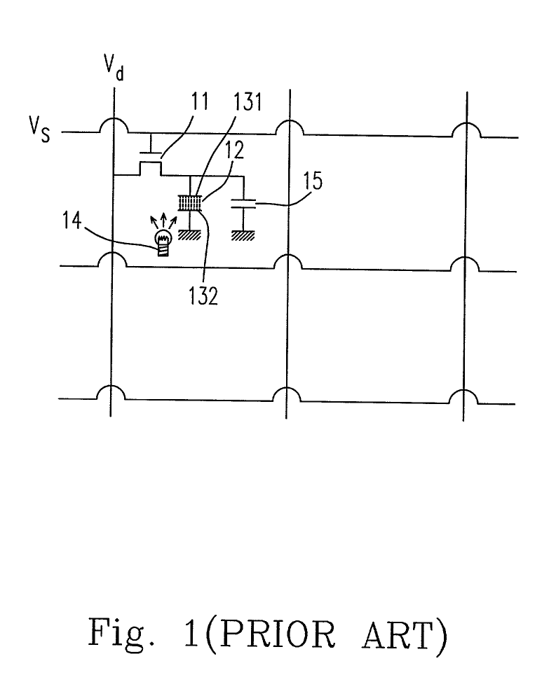

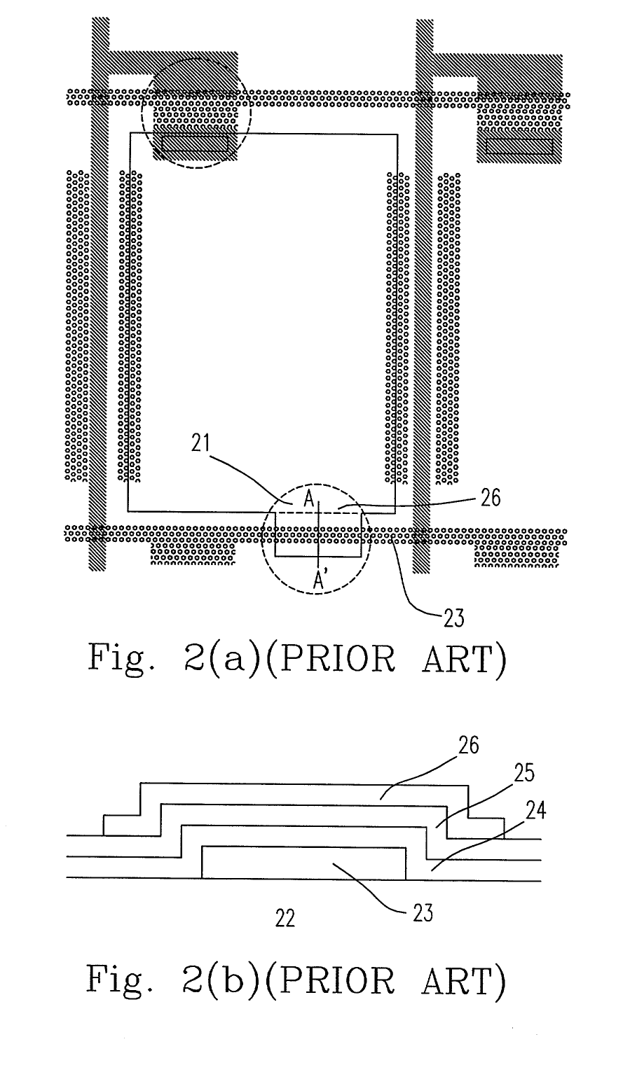

### DETAILED DESCRIPTION OF THE PREFERRED EMBODIMENTS

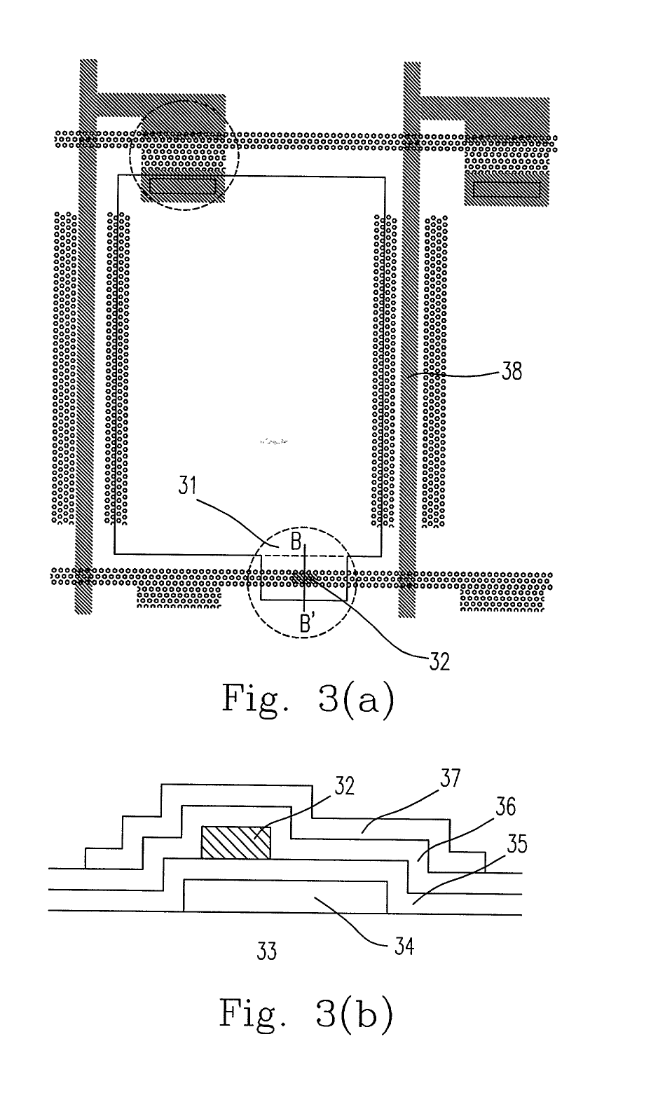

Please refer to FIGS. 3(a) and 3(b). The repair structure provided by the present invention is co-constructed with a storage capacitance 31 in a pixel unit. A first conducting structure 34 (i.e. the gate conducting structure of the pixel unit), a first insulating structure 35 (i.e. the gate insulating layer of the pixel unit), a wrapped conducting structure 32, a second insulating structure 36 (i.e. the protecting layer of the pixel unit), and a second conducting structure 37 are formed in sequence on a glass substrate 33. Especially, the wrapped conducting structure 32 formed on the first insulating structure 35 is formed simultaneously with the data line structure, and then wrapped by the second insulating structure 36.

For repairing the defects of the thin film transistor-liquid crystal display, the first insulating structure 35 and the second insulating structure 36 are destroyed by a laser, and the welding effect is improved by the wrapped conducting structure 32. Thus, an electrical connection between the second conducting structure 37, the wrapped conducting structure 35 and the first conducting structure 34 is made.

The first conducting structure 34 and the wrapped cinducting structure 32 could be made of a material selected from a group consisting of chromium, molybdenum, tungsten molybdate, titanium, tantalum, aluminum, copper, and the combination thereof. The first insulating structure 35 and the second insulating structure 36 could be made of a material selected from a group consisting of silicon oxide, silicon nitride and silicon oxynitride. The second conducting structure 37 could be made of a material selected from a group consisting of indium oxide, tin oxide and indium tin oxide, and formed simultaneously with the pixel of the thin film transistor-liquid crystal display.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1.A repair structure co-constructed with a storage capacitance in a pixel unit of a thin film transistor-liquid crystal display for repairing defects of said thin film transistor-liquid crystal display, comprising:
a first conducting structure as a first electrode of said storage capacitance;
an insulating structure formed on said first conducting structure to be a dielectric material of said storage capacitance;
a wrapped conducting structure wrapped in said insulating structure; and
a second conducting structure as a second electrode of said storage capacitance, wherein when said storage capacitance is welded, said defects are repaired by said wrapped conducting structure.

2. The repair structure according to claim 1, wherein said insulating structure comprises:
a first insulating structure formed on said first conducting structure; and
a second insulating structure formed under said second conducting structure, wherein said wrapped conducting structure is wrapped by said first insulating structure and said second insulating structure.

3. The repair structure according to claim 2, wherein said first insulating structure is a gate insulating layer of said thin film transistor-liquid crystal display and made of a material selected from a group consisting of silicon oxide, silicon nitride and silicon oxynitride.

4. The repair structure according to claim 2, wherein said second insulating structure is a protecting layer and made of a material selected from a group consisting of silicon oxide, silicon nitride and silicon oxynitride.

5. The repair structure according to claim 1, wherein said first electrode is made of a material selected from a group consisting of chromium, molybdenum, tungsten molybdate, titanium, tantalum, aluminum, copper, and the combination thereof.

6. The repair structure according to claim 1, wherein said second electrode is made of a material selected from a group consisting of indium oxide, tin oxide and indium tin oxide.

7. The repair structure according to claim 1, wherein when said insulating structure is destroyed by a laser, an electrical connection between said second conducting structure, said wrapped conducting structure and said first conducting structure is made.

8. A method for fabricating a repair structure co-constructed with a storage capacitance in a pixel unit of a thin film transistor-liquid crystal display for repairing defects of said thin film transistor-liquid crystal display, comprising steps of:
a) forming a first conducting structure as a first electrode of said storage capacitance;
b) forming a first insulating structure on said first conducting structure;
c) forming a wrapped conducting structure on said first insulating structure;
d) forming a second insulating structure on said first insulating structure and said wrapped conducting structure, wherein said wrapped conducting structure is wrapped by said first insulating structure and said second insulating structure; and
e) forming a second conducting structure as a second electrode of said storage capacitance on said second insulating structure, wherein when said storage capacitance is welded, said defects are repaired by said wrapped conducting structure.

9. The method according to claim 8, wherein said first conducting structure is made of a material selected from a group consisting of chromium, molybdenum, tungsten molybdate, titanium, tantalum, aluminum, copper and the combination thereof.

10. The method according to claim 8, wherein said first insulating structure is a gate insulating layer of said thin film transistor-liquid crystal display and made of a material selected from a group consisting of silicon oxide, silicon nitride and silicon oxynitride.

11. The method according to claim 8, wherein said wrapped conducting structure is made of a material selected from a group consisting of chromium, molybdenum, tungsten molybdate, titanium, tantalum, aluminum, copper, and the combination thereof.

12. The method according to claim 8, wherein said second insulating structure is a protecting layer and made of a material selected from a group consisting of silicon oxide, silicon nitride and silicon oxynitride.

13. The method according to claim 8, wherein said second conducting structure is made of a material selected from a group consisting of indium oxide, tin oxide and indium tin oxide.

14. The method according to claim 8, wherein when said insulating structure is destroyed by a laser, an electrical connection between said second conducting structure, said wrapped conducting structure and said first conducting structure is made.

15. The method according to claim 8, wherein said wrapped conducting structure is formed simultaneously with a data line structure of said thin film transistor-liquid crystal display.
